(19) United States
(12) Patent Application Publication
(10) Pub. No.: US 2013/0260108 A1
(43) Pub. Date: Oct. 3, 2013

(54) PHOTO-CURING POLYSILOXAN COMPOSITION AND APPLICATIONS THEREOF

(71) Applicant: CHI MEI CORPORATION, Tainan (TW)

(72) Inventors: Ming-Ju Wu, Tainan (TW); Chun-An Shih, Tainan (TW)

(73) Assignee: CHI MEI CORPORATION, Tainan (TW)

(21) Appl. No.: 13/792,513

(22) Filed: Mar. 11, 2013

(30) Foreign Application Priority Data
Mar. 29, 2012 (TW) 101111120

(51) Int. Cl. G03F 7/075

(52) U.S. Cl. CPC G03F 7/0757
USPC 428/195.1; 430/286.1

(57) ABSTRACT

A photo-curing polysiloxane composition includes a polysiloxane, a quinonediazidesulfonic acid ester, a fluorene-containing compound, and a solvent. The polysiloxane is obtained by subjecting a silane monomer component to condensation. A protective film formed from the photo-curing polysiloxane composition, and an element containing the protective film, are also discussed.

### CROSS-REFERENCE TO RELATED APPLICATION

This application claims priority of Taiwanese Application No. 101111120, filed on Mar. 29, 2012.

### BACKGROUND OF THE INVENTION

1. Field of the Invention

This invention relates to a photo-curing polysiloxane composition, more particularly to a photo-curing polysiloxane composition including a polysiloxane and a fluorene-containing compound, a protective film formed from the photo-curing polysiloxane composition, and an element containing the protective film.

2. Description of the Related Art

In recent years, in the field of integrated circuits used in the semiconductor industry, liquid crystal displays, and organic electroluminescence displays, it is required that the pattern details in photolithography process be finer due to element miniaturization.

Positive type photosensitive materials with high resolution and high sensitivity are adopted to obtain miniaturized patterns via exposure and development. The positive type photosensitive material containing a polysiloxane composition has been widely used in the art.

JP 2008-107529 discloses a photosensitive resin composition capable of forming a cured film. The photosensitive resin composition includes a polysiloxane, a quinonediazidesulfonic acid ester, and a solvent. The polysiloxane is obtained by subjecting a silane monomer containing a glycidyl group or a succinic anhydride group to hydrolysis and partial condensation. Although the photosensitive resin composition has acceptable sensitivity in the industry, the cured film formed therefrom has inferior chemical resistance and hardness.

It is still required in the art to provide a photosensitive resin composition with high sensitivity and a protective film formed therefrom with better chemical resistance and hardness.

### SUMMARY OF THE INVENTION

A first object of this invention is to provide a photo-curing polysiloxane composition having high sensitivity.

A second object of this invention is to provide a protective film with better chemical resistance and better hardness.

A third object of this invention is to provide an element having the protective film.

According to a first aspect of this invention, there is provided a photo-curing polysiloxane composition including a polysiloxane (A), a quinonediazidesulfonic acid ester (B), a fluorene-containing compound (C), and a solvent (D). The polysiloxane (A) is obtained by subjecting a silane monomer component to condensation.

The silane monomer component includes a silane monomer of Formula (I):

Si(R^{a})ₜ(OR^{b})₄₋ₜ (I)

wherein

t is an integer ranging from 1 to 3;

when t is 1, R^{a} is selected from the group consisting of an anhydride-substituted C₁-C₁₀ alkyl group, an epoxy-substituted C₁-C₁₀ alkyl group, and an epoxy-substituted alkoxy group;

when t is 2 or 3, at least one of R^{a}s is selected from the group consisting of an anhydride-substituted C₁-C₁₀ alkyl group, an epoxy-substituted C₁-C₁₀ alkyl group, and an epoxy-substituted alkoxy group, and the rest of R^{a}s is selected from the group consisting of hydrogen, a C₁-C₁₀ alkyl group, a C₂-C₁₀ alkenyl group, and a C₆-C₁₅ aryl group, R^{a}s being identical or different; and

R^{b} is selected from the group consisting of a hydrogen atom, a C₁-C₆ alkyl group, a C₁-C₆ acyl group, and a C₆-C₁₅ aryl group, R^{b}s being identical or different when 4-t is 2 or 3.

The fluorene-containing compound is represented by Formula (II):

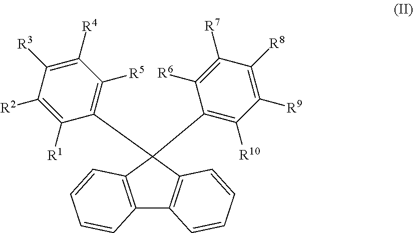

wherein

at least one of R¹-R¹⁰ includes a reactive group which is selected from the group consisting of an epoxy-containing group, a carboxy-containing group, an anhydride-containing group, and an amino-containing group. When the at least one of R^{a} is the epoxy-substituted C₁-C₁₀ alkyl group or the epoxy-substituted alkoxy group, the reactive group is not the epoxy-containing group.

According to a second aspect of this invention, there is provided a protective film formed by applying the photo-curing polysiloxane composition on a substrate.

According to a third aspect of this invention, there is provided an element including the protective film applied on the substrate.

A dense structure is formed via reaction of the polysiloxane (A) with the fluorene-containing compound (C). The protective film formed from the photo-curing polysiloxane composition thus has better chemical resistance. Meanwhile, the photo-curing polysiloxane composition has high sensitivity in the photolithography process owing to the anhydride group or/and the epoxy group contained in the polysiloxane (A).

### DETAILED DESCRIPTION OF THE PREFERRED EMBODIMENTS

A photo-curing polysiloxane composition in this invention includes a polysiloxane (A), a quinonediazidesulfonic acid ester (B), fluorene-containing compound (C), and a solvent (D).

The polysiloxane (A), the quinonediazidesulfonic acid ester (B), the fluorene-containing compound (C), and the solvent (D) will be described in detail as follows.

### Polysiloxane (A):

The polysiloxane is obtained by subjecting a silane monomer component to condensation. The silane monomer component includes a silane monomer represented by Formula (I):

Si(R^{a})ₜ(OR^{b})₄₋ₜ (I)

wherein

t is an integer ranging from 1 to 3;

when t is 1, R^{a} is selected from the group consisting of an anhydride-substituted C₁-C₁₀ alkyl group, an epoxy-substituted C₁-C₁₀ alkyl group, and an epoxy-substituted alkoxy group;

when t is 2 or 3, at least one of R^{a}s is selected from the group consisting of an anhydride-substituted C₁-C₁₀ alkyl group, an epoxy-substituted C₁-C₁₀ alkyl group, and an epoxy-substituted alkoxy group, and the rest of R^{a}s is selected from the group consisting of hydrogen, a C₁-C₁₀ alkyl group, a C₁-C₁₀ alkenyl group, and a C₆-C₁₅ aryl group, R^{a}s being identical or different; and

R^{b} is selected from the group consisting of a hydrogen atom, a C₁-C₆ alkyl group, a C₁-C₆ acyl group, and a C₆-C₁₅ aryl group, R^{b}s being identical or different when 4-t is 2 or 3.

Examples of the anhydride-substituted C₁-C₁₀ alkyl group include, but are not limited to, ethyl succinic anhydride, propyl succinic anhydride, and propyl glutaric anhydride.

Examples of the epoxy-substituted C₁-C₁₀ alkyl group include, but are not limited to, oxetanylpentyl and 2-(3,4-epoxycyclohexyl)ethyl.

Examples of the epoxy-substituted alkoxy group include, but are not limited to, glycidoxypropyl and 2-oxetanylbutoxy.

In the definition of R^{b}, examples of the alkyl group include, but are not limited to, methyl, ethyl, n-propyl, isopropyl, and n-butyl. A non-limiting example of the acyl group is acetyl. A non-limiting example of the aryl group is phenyl.

Examples of the silane monomer represented by Formula (I) include, but are not limited to, 3-glycidoxypropyltrimethoxysilane (abbreviated as TMS-GAA), 3-glycidoxypropyltriethoxysilane, 2-(3,4-epoxycyclohexyl)ethyltrimethoxysilane, and 2-oxetanylbutoxypropyltriphenoxysilane; commercially available products manufactured by Toagosei Co., Ltd., for example, 2-oxetanylbutoxypropyltrimethoxysilane (trade name: TMSOX-D), 2-oxetanylbutoxypropyltriethoxysilane (trade name: TESOX-D), and 3-triphenoxysilyl propyl succinic anhydride; commercially available products manufactured by Shin-Etsu Chemical Co., Ltd., for example, 3-trimethoxysilyl propyl succinic anhydride (trade name: X-12-967); commercially available products manufactured by Wacker Chemie AG, for example, 3-(triethoxysilyl)propyl succinic anhydride (trade name: GF-20), 3-(trimethoxysilyl)propyl glutaric anhydride (abbreviated as TMSG), 3-(triethoxysilyl)propyl glutaric anhydride, 3-(triphenoxysilyl)propyl glutaric anhydride, diisopropoxy-di(2-oxetanylpropylbutoxypropyl)silane (abbreviated as DIDOS), di(3-oxetanylpentyl)dimethoxy silane, (di-n-butoxysilyl)di(propyl succinic anhydride), (dimethoxysilyl)di(ethyl succinic anhydride), 3-glycidoxypropyldimethylmethoxysilane, 3-glycidoxypropyldimethylethoxysilane, di(2-oxetanylbutoxypentyl)-2-oxetanylpentylethoxy silane, tri(2-oxetanylpentyl)methoxy silane, (phenoxysilyl)tri(propyl succinic anhydride), and (methylmethoxysilyl)di(ethyl succinic anhydride). The aforesaid examples of the silane monomer represented by Formula (I) can be used alone or as a mixture of two or more.

Preferably, the silane monomer component also includes a silane monomer represented by Formula (I-1):

Si(R^{c})ᵤ(OR^{d})₄₋ᵤ (I-1)

wherein

u is an integer ranging from 0 to 3;

R^{c} represents a hydrogen atom, a C₁-C₁₀ alkyl group, a C₂-C₁₀ alkenyl group, or a C₆-C₁₅ aryl group, R^{c}s being identical or different when u is 2 or 3; and

R^{d} represents a hydrogen atom, a C₁-C₆ alkyl group, a C₁-C₆ acyl group, or a C₆-C₁₅ aryl, group, R^{d}s being identical or different when 4-u is 2, 3 or 4.

In the definition of R^{c}, examples of the alkyl group include, but are not limited to, methyl, ethyl, n-propyl, isopropyl, n-butyl, tert-butyl, n-hexyl, n-decyl, trifluoromethyl, 3,3,3-trifluoropropyl, 3-aminopropyl, 3-mercaptopropyl, and 3-isocyanatopropyl. Examples of the alkenyl group include, but are not limited to, vinyl, 3-acryloxypropyl, and 3-methacryloxypropyl. Examples of the aryl group include, but are not limited to, phenyl, tolyl, p-hydroxyphenyl, 1-(p-hydroxyphenyl)ethyl, 2-(p-hydroxyphenyl)ethyl, 4-hydroxy-5-(p-hydroxyphenylcarbonyloxy)pentyl, and naphthyl.

In the definition of R^{d}, examples of the alkyl group include, but are not limited to, methyl, ethyl, n-propyl, isopropyl, and n-butyl. A non-limiting example of the acyl group is acetyl. A non-limiting example of the aryl group is phenyl.

Examples of the silane monomer represented by formula (I-1) include, but are not limited to, tetramethoxysilane, tetraethoxysilane, tetraacetoxysilane, tetraphenoxy silane, methyltrimethoxysilane (abbreviated as MTMS), methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, phenyltrimethoxysilane (abbreviated as PTMS), phenyltriethoxysilane (abbreviated as PTES), p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, dimethyldimethoxysilane (abbreviated as DMDMS), dimethyldiethoxysilane, dimethyldiacetyloxysilane, di-n-butyldimethoxysilane, diphenyldimethoxysilane, trimethylmethoxysilane, tri-n-butylethoxysilane, 3-mercaptopropyltrimethoxysilane, 3-acryoyloxypropyltrimethoxysilane, 3-methyl acryloyloxypropyltrimethoxysilane, and 3-methylacryloyloxypropyltriethoxysilane. The aforesaid examples of the silane monomer represented by formula (I-1) can be used alone or as a mixture of two or more.

Preferably, the silane monomer component also includes a siloxane prepolymer of Formula (I-2):

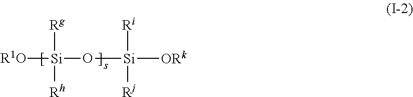

wherein

R⁵, R^{h}, Rⁱ and R^{j} independently represent a hydrogen atom, a substituted or unsubstituted C₁-C₁₀ alkyl group, a substituted or unsubstituted C₂-C₆ alkenyl group, or a substituted or unsubstituted C₆-C₁₅ aryl group. The plural R^{g}s and R^{h}s can be respectively identical with or different from each other when s ranges from 2 to 1,000. Examples of the alkyl group include, but are not limited to, methyl, ethyl, and n-propyl. Examples of the alkenyl group include, but are not limited to, vinyl, acryloxypropyl, and methacryloxypropyl. Examples of the aryl group include, but are not limited to, phenyl, tolyl, and naphthyl.

R¹ and R^{k} independently represent a hydrogen atom, a substituted or unsubstituted C₁-C₆ alkyl group, a substituted or unsubstituted C₁-C₆ acyl group, or a substituted or unsubstituted C₆-C₁₅ aryl group. Examples of the alkyl group include, but are not limited to, methyl, ethyl, n-propyl, isopropyl, and n-butyl. A non-limiting example of the acyl group is acetyl. A non-limiting example of the aryl group is phenyl.

In Formula (I-2), s is an integer ranging from 1 to 1,000, preferably from 3 to 300, and more preferably from 5 to 200.

Examples of the siloxane prepolymer represented by formula (I-2) include, but are not limited to, 1,1,3,3-tetramethyl-1,3-dimethoxy disiloxane, 1,1,3,3-tetramethyl-1,3-diethoxydisiloxane, 1,1,3,3-tetraethyl-1,3-diethoxydisiloxane, and commercially available silanol terminal polysiloxanes manufactured by Gelest Inc. (for example, DM-S12 (molecular weight: 400-700), DMS-S15 (molecular weight: 1,500-2,000), DMS-S21 (molecular weight: 4,200), DMS-S27 (molecular weight: 18,000), DMS-S31 (molecular weight: 26,000), DMS-S32 (molecular weight: 36,000), DMS-S33 (molecular weight: 43,500), DMS-S35 (molecular weight: 49,000), DMS-S38 (molecular weight: 58,000), DMS-S42 (molecular weight: 77,000), PDS-9931 (molecular weight: 1,000-1,400), and the like). The aforesaid examples of the siloxane prepolymer can be used alone or as a mixture of two or more.

Preferably, the silane monomer component additionally includes silicon dioxide particles. There is no specific limitation to the mean particle size of the silicon dioxide particles. The mean particle size of the silicon dioxide particles ranges generally from 2 nm to 250 nm, preferably from 5 nm to 200 nm, and more preferably from 10 nm to 100 nm.

Examples of the silicon dioxide particles include, but are not limited to, commercially available products manufactured by JGC Catalysts and Chemicals Ltd., for example, OSCAR 1132 (particle size: 12 nm, dispersant: methanol), OSCAR 1332 (particle size: 12 nm, dispersant: n-propanol), OSCAR 105 (particle size: 60 nm, dispersant: γ-butyrolactone), OSCAR 106 (particle size: 120 nm, dispersant: diacetone alcohol), and the like; commercially available products manufactured by Fuso Chemical Co., Ltd., for example, Quartron PL-1-IPA (particle size: 13 nm, dispersant: isopropanone), Quartron PL-1-TOL (particle size: 13 nm, dispersant: toluene), Quartron PL-2L-PGME (particle size: 18 nm, dispersant: propylene glycol monomethyl ether), Quartron PL-2L-MEK (particle size: 18 nm, dispersant: methyl ethyl ketone), and the like; and commercially available products manufactured by Nissan Chemical, for example, IPA-ST (particle size: 12 nm, dispersant: isopropanol), EG-ST (particle size: 12 nm, dispersant: ethylene glycol), IPA-ST-L (particle size: 45 nm, dispersant: isopropanol), IPA-ST-ZL (particle size: 100 nm, dispersant: isopropanol), and the like. The aforesaid examples of the silicon dioxide particles can be used alone or as a mixture of two or more.

The condensation can be conducted in a manner well known in the art. For example, a solvent, water, and optionally a catalyst are added to the silane monomer component, followed by stirring at a temperature ranging from 50° C. to 150° C. for 0.5 hour to 120 hours. During stirring, the by-products, such as alcohols, water, and the like, can be removed by distillation, if necessary.

There is no specific limitation to the solvent, which can be identical with or different from the solvent (D) contained in the photo-curing polysiloxane composition. Preferably, the solvent is used in an amount ranging from 15 g to 1,200 g, preferably from 20 g to 1,100 g, and more preferably from 30 g to 1,000 g based on 100 g of the silane monomer component.

The amount of water for the hydrolysis ranges from 0.5 mole to 2 moles based on 1 mole of the hydrolyzable groups contained in the silane monomer component.

There is no specific limitation to the catalyst, and an acid catalyst or a base catalyst can be used. Examples of the acid catalyst include, but are not limited to, hydrochloric acid, nitric acid, sulfuric acid, hydrofluoric acid, oxalic acid, phosphoric acid, acetic acid, trifluoroacetic acid, formic acid, polycarboxylic acids and anhydrides thereof, and ion exchange resins. Examples of the base catalyst include, but are not limited to, diethylamine, triethylamine, tripropylamine, tributylamine, tripentylamine, trihexylamine, triheptylamine, trioctylamine, diethanolamine, triethanolamine, sodium hydroxide, potassium hydroxide, alkoxysilanes containing an amino group, and ion exchange resins.

Preferably, the catalyst is used in an amount ranging generally from 0.005 g to 15 g, preferably from 0.01 g to 12 g, and more preferably from 0.05 g to 10 g based on 100 g of the silane monomer component.

In view of storage stability, it is preferable that the by-products (for example, alcohols and water) and the catalyst are not contained in the polysiloxane (A) produced after condensation. Therefore, it is preferable to purify the polysiloxane (A). There is no specific limitation to the purification method. Preferably, the polysiloxane (A) is diluted with a hydrophobic solvent, and an organic layer washed with water several times is then concentrated with an evaporator to remove alcohols or water. Additionally, the catalyst can be removed using ion exchange resin.

If the polysiloxane (A) does not contain anhydride group or/and epoxy group, the polysiloxane (A) cannot conduct a cross-linking reaction with the fluorene-containing compound (C) represented by Formula (H). Therefore, a dense structure against swelling of the polysiloxane (A) attributed to the solvent is not formed, which hence leads to deteriorated chemical resistance. Furthermore, the polysiloxane (A) in this invention contains anhydride group or/and epoxy group which can result in lower exposure energy or shorter exposure duration during exposure step. Sensitivity of the photo-curing polysiloxane composition according to this invention is therefore increased, and acidic groups can be effectively produced. Subsequent photolithography process can be facilitated thereby.

### Quinonediazidesulfonic Acid Ester (B):

There is no specific limitation to the quinonediazidesulfonic acid ester (B) suitable in the photo-curing polysiloxane composition of the present invention. The quinonediazidesulfonic acid ester (B) can be a fully or partially esterified compound. Preferably, the quinonediazidesulfonic acid ester (B) is obtained via a reaction of o-naphthoquinonediazidesulfonic acid or salt thereof with a hydroxyl compound. More preferably, the quinonediazidesulfonic acid ester (B) is obtained via a reaction of o-naphthoquinonediazidesulfonic acid or salt thereof with a polyhydroxyl compound.

Examples of the o-naphthoquinonediazidesulfonic acid include, but are not limited to, o-naphthoquinonediazide-4-sulfonic acid, o-naphthoquinonediazide-5-sulfonic acid, and o-naphthoquinonediazide-6-sulfonic acid. A non-limiting example of the salt of o-naphthoquinonediazidesulfonic acid is halide of o-naphthoquinonediazidesulfonic acid.

Examples of the hydroxyl compound include, but are not limited to

(1)hydroxybenzophenone compounds, for example, but not limited to, 2,3,4-trihydroxybenzophenone, 2,4,4′-trihydroxybenzophenone, 2,4,6-trihydroxybenzophenone, 2,3,4,4′-tetrahydroxybenzophenone, 2,4,2′,4′-tetrahydroxybenzophenone, 2,4,6,3′,4′-pentahydroxybenzophenone, 2,3,4,2′,4′-pentahydroxybenzophenone, 2,3,4,2′,5′-pentahydroxybenzophenone, 2,4,5,3′,5′-pentahydroxybenzophenone, and 2,3,4,3′,4′,5′-hexahydroxybenzophenone.
(2) hydroxyaryl compounds, for example, but not limited to, a hydroxyaryl compound represented by Formula (a):

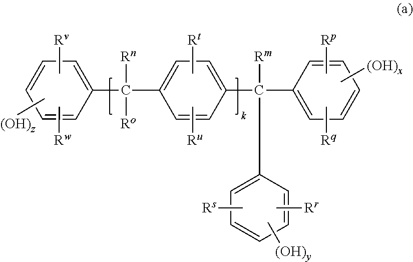

wherein

R^{m}, Rⁿ, and R^{o} independently represent a hydrogen atom or a C₁-C₆ alkyl group;

R^{p}, R^{q}, R^{r}, R^{s}, R^{t}, and R^{u} independently represent a hydrogen atom, a halogen atom, a C₁-C₆ alkyl group, a C₁-C₆ alkoxy group, a C₁-C₆ alkenyl group, or a cycloalkyl group;

R^{v} and R^{w} independently represent a hydrogen atom, a halogen atom, or a C₁-C₆ alkyl group;

x, y, and z independently denote an integer ranging from 1 to 3; and

k is 0 or 1.

Examples of the hydroxyaryl compound represented by Formula (a) include, but are not limited to, tri(4-hydroxyphenyl)methane, bis(4-hydroxy-3,5-dimethylphenyl)-4-hydroxyphenylmethane, bis(4-hydroxy-3,5-dimethylphenyl)-3-hydroxyphenylmethane, bis(4-hydroxy-3,5-dimethylphenyl)-2-hydroxyphenylmethane, bis(4-hydroxy-2,5-dimethylphenyl)-4-hydroxyphenylmethane, bis(4-hydroxy-2,5-dimethylphenyl)-3-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3,5-dimethylphenyl)-2,4-dihydroxyphenylmethane, bis(4-hydroxy-2,5-dimethylphenyl)-2,4-dihydroxyphenyl methane, bis(4-hydroxyphenyl)-3-methoxy-4-hydroxyphenylmethane, bis(3-cyclohexyl-4-hydroxyphenyl)-3-hydroxyphenylmethane, bis(3-cyclohexyl-4-hydroxyphenyl)-2-hydroxyphenylmethane, bis(3-cyclohexyl-4-hydroxyphenyl)-4-hydroxyphenylmethane, bis(3-cyclohexyl-4-hydroxy-6-methylphenyl)-2-hydroxyphenylmethane, bis(3-cyclohexyl-4-hydroxy-6-methylphenyl)-3-hydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, bis(3-cyclohexyl-6-hydroxyphenyl)-3-hydroxyphenylmethane, bis(3-cyclohexyl-6-hydroxyphenyl)-4-hydroxyphenylmethane, bis(3-cyclohexyl-6-hydroxyphenyl)-2-hydroxyphenylmethane, bis(3-cyclohexyl-6-hydroxy-4-methylphenyl)-2-hydroxyphenylmethane, bis(3-cyclohexyl-6-hydroxy-4-methylphenyl)-4-hydroxyphenylmethane, bis(3-cyclohexyl-6-hydroxy-4-methylphenyl)-3,4-di hydroxyphenylmethane, 1-[1-(4-hydroxyphenyl)isopropyl]-4-[1,1-bis(4-hydroxyphenyl)ethyl]benzene, and 1-[1-(3-methyl-4-hydroxyphenyl)isopropyl]-4-[1,1-bis(3-methyl-4-hydroxyphenyl)ethyl]benzene.

(3) (hydroxyphenyl)hydrocarbon compounds, for example, but not limited to, a (hydroxyphenyl)hydrocarbon compound represented by Formula (b):

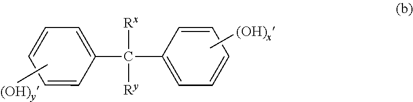

wherein

R^{x} and R^{y} independently represent a hydrogen atom or a C₁-C₆ alkyl group; and

x′ and y′ independently represent an integer ranging from 1 to 3.

Examples of the (hydroxyphenyl)hydrocarbon compound represented by Formula (b) include, but are not limited to, 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, bis(2,3,4-trihydroxyphenyl)methane, and bis(2,4-dihydroxyphenyl)methane.

(4) other aromatic hydroxyl compounds, for example, but not limited to, phenol, p-methoxyphenol, dimethylphenol, hydroquinone, bisphenol A, naphthol, pyrocatechol, pyrogallol monomethyl ether, pyrogallol-1,3-dimethyl ether, gallic acid, and partially esterified or partially etherified gallic acid.

The aforesaid examples of the hydroxyl compounds can be used alone or as a mixture of two or more.

The preferred examples of the hydroxyl compounds include 1-[1-(4-hydroxyphenyl) isopropyl]-4-[1,1-bis(4-hydroxyphenyl)ethyl]benzene, 2,3,4-trihydroxybenzophenone, and 2,3,4,4′-tetrahydroxybenzophenone, and combinations thereof.

The reaction of o-naphthoquinonediazidesulfonic acid or salt thereof with the hydroxyl compound is often conducted in an organic solvent such as dioxane, N-pyrrolidone, acetamide, and the like, in the presence of an alkali condensation agent such as triethanolamine, alkali carbonate, alkali hydrogen carbonate, and the like.

Preferably, the esterification rate of the quinonediazidesulfonic acid ester (B) is more than 50%. That is, more than 50% by mole of the hydroxyl group contained in the hydroxyl compound undergoes an esterification reaction with o-naphthoquinonediazidesulfonic acid or salt thereof, based on 100% by mole of the total hydroxyl group contained in the hydroxyl compound. More preferably, the esterification rate of the quinonediazide sulfonate compound is more than 60%.

The quinonediazidesulfonic acid ester (B) is used in an amount ranging from 1 part by weight to 50 parts by weight, preferably from 2 parts by weight to 40 parts by weight, and more preferably from 3 parts by weight to 30 parts by weight based on 100 parts by weight of the polysiloxane (A).

### Fluorene-Containing Compound (C):

The fluorene-containing compound (C) is represented by Formula (II):

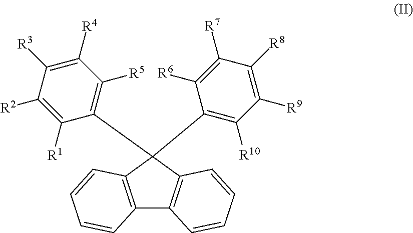

wherein

at least one of R¹-R¹⁰ includes a reactive group which is selected from the group consisting of an epoxy-containing group, a carboxy-containing group, an anhydride-containing group, and an amino-containing group.

Preferably, the at least one of R^{a} in formula (I) is an anhydride-substituted C₁-C₁₀ alkyl group, and the reactive group in formula (II) is an epoxy-containing group. The abovementioned functional groups together can form a dense structure against swelling of the polysiloxane (A) attributed to the solvent, and therefore can lead to better chemical resistance.

Preferably, the at least one of R^{a} in formula (I) is an epoxy-substituted C₁-C₁₀ alkyl group or an epoxy-substituted alkoxy group, and the reactive group in formula (II) is a carboxy-containing group or an amino-containing group. The abovementioned functional groups together can form a dense structure against swelling of the polysiloxane (A) attributed to the solvent, and therefore can lead to better chemical resistance.

For R¹-R¹⁰ in Formula (II), the groups other than the at least one reactive group include a hydrogen atom, a hydroxyl group, an alkyl group, an aryl group, an alkoxy group, and combinations of the aforesaid groups.

Examples of the fluorene-containing compound (C) include, but are not limited to, epoxy-containing fluorene compounds, for example, 9,9-bis[(4-glycidoxy)phenyl]fluorene, 9,9-bis[4-(2-glycidoxyethoxy)phenyl]fluorene, 9,9-bis{4-[2-(3,4-epoxycyclohexyl)ethoxy]phenyl}fluorene, 9,9-bis(3-t-butyl-4-glycidoxy-5-methylphenyl)fluorene, 9,9-bis(3-phenyl-4-glycidoxyphenyl)fluorene, 9,9-bis(4-glycidoxy-3-methylphenyl)fluorene, 9,9-bis(3,4-diglycidoxy phenyl)fluorene, 9,9-bis[4-[2-(3-oxetanyl)]butoxy]biphenyl fluorene, and the like; and carboxy-containing or anhydride-containing fluorene compounds, for example, 9,9-bis(3,4-dicarboxyphenyl)fluorene dianhydride, 9,9-bis[4-(3,4-dicarboxyphenoxy)phenyl]fluorene dianhydride, and the like; and amino-containing fluorene compounds, for example, 9,9-bis(4-aminophenyl)fluorene, 9,9-bis(3-amino-4-hydroxyphenyl)fluorene, 9,9-bis(aminomethylphenyl)fluorene, 9,9-bis(4-amino-3-fluorophenyl)fluorene, and the like. The aforesaid examples of fluorene-containing compound (C) of Formula (II) can be used alone or as a mixture of two or more.

The fluorene-containing compound (C) of Formula (II) is used in an amount ranging from 5 parts by weight to 120 parts by weight, preferably from 10 parts by weight to 100 parts by weight, and more preferably from 20 parts by weight to 80 parts by weight based on 100 parts by weight of the polysiloxane (A).

If the fluorene-containing compound (C) of Formula (II) is not added, cross-linking reaction between the anhydride-containing or epoxy-containing polysiloxane (A) and the fluorene-containing compound (C) cannot be conducted. Therefore, a dense structure against swelling of the polysiloxane (A) attributed to the solvent is not formed, which can lead to deteriorated chemical resistance.

When R^{a} and R¹-R¹⁰ are all epoxy groups, cross-linking reaction between the fluorene-containing compound (C) of Formula (II) and the polysiloxane (A) is not easy to take place. Therefore, a dense structure against swelling of the polysiloxane (A) attributed to the solvent is not formed, which can lead to deteriorated chemical resistance. Besides, compatibility between the unreacted fluorene-containing compound (C) of Formula (II) and the components of the protective film formed from the photo-curing polysiloxane composition is not good, which results in deteriorated hardness of the protective film owing to poor distribution of the unreacted fluorene-containing compound (C).

### Solvent (D):

There is no specific limitation to the solvent (D) suitable in the photo-curing polysiloxane composition of the present invention. Examples of the solvent (D) include, but are not limited to, an alcoholic hydroxyl-containing compound, and a carbonyl-containing cyclic compound. The aforesaid examples of solvent (D) can be used alone or as a mixture of two or more.

Examples of the alcoholic hydroxyl-containing compound include, but are not limited to, acetol, 3-hydroxy-3-methyl-2-butanone, 4-hydroxy-3-methyl-2-butanone, 5-hydroxy-2-pentanone, 4-hydroxy-4-methyl-2-pentanone (diacetone alcohol, abbreviated as DAA), ethyl lactate, butyl lactate, propylene glycol monomethyl ether, propylene glycol monoethyl ether (abbreviated as PGEE), propylene glycol monomethylether acetate (abbreviated as PGMEA), propylene glycol mono-n-propyl ether, propylene glycol mono-n-butyl ether, propylene glycol mono-t-butyl ether, 3-methoxy-1-butanol, 3-methyl-3-methoxy-1-butanol, and combinations thereof. The aforesaid examples of the alcoholic hydroxyl-containing compound can be used alone or as a mixture of two or more.

Preferably, the alcoholic hydroxyl-containing compound is selected from diacetone alcohol, ethyl lactate, propylene glycol monoethyl ether, propylene glycol monomethylether acetate, and combinations thereof.

Examples of the carbonyl-containing cyclic compound include, but are not limited to, γ-butyrolactone, γ-valerolactone, δ-valerolactone, propylene carbonate, N-methylpyrrolidone, cyclohexanone, and cycloheptanone. The aforesaid examples of the carbonyl-containing cyclic compound can be used alone or as a mixture of two or more.

Preferably, the carbonyl-containing cyclic compound is selected from γ-butyrolactone, N-methylpyrrolidone, cyclohexanone, and combinations thereof.

When the alcoholic hydroxyl-containing compound and the carbonyl-containing cyclic compound are used in combination, there is no specific limitation to the weight ratio thereof. The weight ratio of the alcoholic hydroxyl-containing compound to the carbonyl-containing cyclic compound ranges preferably from 99/1 to 50/50, and more preferably from 95/5 to 60/40. It should be noted that, when the weight ratio of the alcoholic hydroxyl-containing compound to the carbonyl-containing cyclic compound ranges from 99/1 to 50/50, it is less likely for the unreacted silanol group in polysiloxane (A) to undergo condensation reaction that may reduce the storage stability. Moreover, the miscibility between the polysiloxane (A) and the quinonediazidesulfonic acid ester (B) is good, so that it is less likely to cause the protective film to become opaque, thereby maintaining the transparency of the protective film.

Further solvents other than the aforesaid solvent can be included in the photo-curing polysiloxane composition of the present invention as long as the desirable effects obtainable by the photo-curing polysiloxane composition are not impaired. Examples of the further solvents include, but are not limited to: (1) esters, for example, ethyl acetate, n-propyl acetate, isopropyl acetate, n-butyl acetate, isobutyl acetate, propylene glycol monomethyl ether acetate, 3-methoxy-1-butyl acetate, 3-methyl-3-methoxy-1-butyl acetate, and the like; (2) ketones, for example, methyl isobutyl ketone, diisopropyl ketone, diisobutyl ketone, and the like; and (3) ethers, for example, diethyl ether, diisopropyl ether, di-n-butyl ether, diphenyl ether, and the like.

The solvent (D) is used in an amount ranging generally from 50 parts by weight to 1,200 parts by weight, preferably from 80 parts by weight to 1,000 parts by weight, and more preferably from 100 parts by weight to 800 parts by weight based on 100 parts by weight of polysiloxane (A).

### Thermal Acid Generator (E):

Preferably, the photo-curing polysiloxane composition also includes a thermal acid generator (E).

Examples of the thermal acid generator (E) include, but are not limited to, 4-hydroxyphenyldimethylsulfonium, benzyl-4-hydroxyphenylmethylsulfonium, 2-methylbenzyl-4-hydroxyphenylmethylsulfonium, 2-methylbenzyl-4-acetylphenylmethylsulfonium, 2-methylbenzyl-4-benzoyloxyphenylmethylsulfonium, and methanesulfonates, trifluoromethanesulfonates, camphorsulfonates, p-toluenesulfonates, or the likes thereof; commercially available products manufactured by Sanshin Chemical Industry Co. Ltd. (for example, SI-60, SI-80, SI-100, SI-110, SI-145, SI-150, SI-60L, SI-80L, SI-100L, SI-110L, SI-145L, SI-150L, SI-160L, SI-180L), and combinations thereof. The aforesaid Examples of the thermal acid generator (E) can be used alone or as a mixture of two or more.

Preferably, the thermal acid generator (E) is selected from 4-hydroxyphenyldimethylsulfonium, benzyl-4-hydroxyphenylmethylsulfonium, 2-methylbenzyl-4-hydroxyphenylmethylsulfonium, 2-methylbenzyl-4-acetylphenylmethylsulfonium, 2-methylbenzyl-4-benzoyloxyphenylmethylsulfonium, and methanesulfonates, trifluoromethanesulflates, camphorsulfonates and p-toluenesulfonates thereof, and combinations thereof.

The thermal acid generator is used in an amount ranging preferably from 0.5 part by weight to 20 parts by weight, more preferably from 1 part by weight to 15 parts by weight, and most preferably from 1 part by weight to 10 parts by weight based on 100 parts by weight of polysiloxane (A).

The thermal acid generator (E) is able to promote the cross-linking reaction between the fluorene-containing compound (C) represented by Formula (II) and the anhydride-containing or epoxy-containing polysiloxane (A). Therefore, the polysiloxane (A) is able to resist swelling attributed to the solvent and chemical resistance can be enhanced.

### Additives (F):

Additives (F) can be optionally added to the photo-curing polysiloxane composition, and include, but are not limited to, a sensitizer, an adhesion auxiliary agent, a surfactant, a solubility promoter, a defoamer, and combinations thereof.

There is no specific limitation to the sensitizer. Preferably, the sensitizer is a phenolic hydroxyl-containing compound, for example, but not limited to: (1) trisphenol type compounds, for example, tri(4-hydroxyphenyl)methane, bis(4-hydroxy-3-methylphenyl)-2-hydroxyphenylmethane, bis(4-hydroxy-2,3,5-trimethylphenyl)-2-hydroxyphenylmethane, bis(4-hydroxy-3,5-dimethylphenyl)-4-hydroxyphenylmethane, bis(4-hydroxy-3,5-dimethylphenyl)-3-hydroxyphenylmethane, bis(4-hydroxy-3,5-methylphenyl)-2-hydroxyphenylmethane, bis(4-hydroxy-2,5-dimethylphenyl)-4-hydroxyphenyl methane, bis(4-hydroxy-2,5-dimethylphenyl)-3-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-2,5-dimethylphenyl)-2,4-dihydroxyphenyl methane, bis(4-hydroxyphenyl)-3-methoxy-4-hydroxyphenylmethane, bis(5-cyclohexyl-4-hydroxy-2-methylphenyl)-4-hydroxyphenylmethane, bis(5-cyclohexyl-4-hydroxy-2-methylphenyl)-3-hydroxyphenylmethane, bis(5-cyclohexyl-4-hydroxy-2-methylphenyl)-2-hydroxyphenylmethane, bis(5-cyclohexyl-4-hydroxy-2-methylphenyl)-3,4-dihydroxyphenylmethane, and the like; (2) bisphenol type compounds, for example, bis(2,3,4-trihydroxyphenyl)methane, bis(2,4-dihydroxyphenyl)methane, 2,3,4-trihydroxyphenyl-4′-hydroxyphenylmethane, 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, 2-(3-fluoro-4-hydroxyphenyl)-2-(3′-fluoro-4′-hydroxyphenyl)propane, 2-(2,4-dihydroxyphenyl)-2-(4′-hydroxyphenyl)propane, 2-(2,3,4-trihydroxyphenyl)-2-(4′-hydroxyphenyl)propane, 2-(2,3,4-trihydroxyphenyl)-2-(4′-hydroxy-3′,5′-dimethylphenyl)propane, and the like; (3) polynuclear branched compounds, for example, 1-[1-(4-hydroxyphenyl)isopropyl]-4-[1,1-bis(4-hydroxyphenyl)ethyl]benzene, 1-[1-(3-methyl-4-hydroxyphenyl]isopropyl]-4-[1,1-bis(3-methyl-4-hydroxyphenyl)ethyl]benzene, and the like; (4) condensation type phenol compounds, for example, 1,1-bis(4-hydroxyphenyl)cyclohexane, and the like; (5) polyhydroxy benzophenones, for example, 2,3,4-trihydroxybenzophenone, 2,4,4′-trihydroxybenzophenone, 2,4,6-trihydroxybenzophenone, 2,3,4-trihydroxy-2′-methylbenzophenone, 2,3,4,4′-tetrahydroxybenzophenone, 2,4,2′,4′-tetrahydroxybenzophenone, 2,4,6,3′,4′-pentahydroxybenzophenone, 2,3,4,2′,4′-pentahydroxybenzophenone, 2,3,4,2′,5′-pentahydroxybenzophenone, 2,4,6,3′,4′,5′-hexahydroxybenzophenone, 2,3,4,3′,4′,5′-hexahydroxybenzophenone, and the like; and combinations thereof.

The sensitizer is used in an amount ranging preferably from 5 to 50 parts by weight, more preferably from 8 to 40 parts by weight, and most preferably from 10 to 35 parts by weight based on 100 parts by weight of the polysiloxane (A).

The adhesion auxiliary agent is used to enhance the adhesion of the photo-curing polysiloxane composition of the present invention to a substrate containing a semiconductor material. Examples of the adhesion auxiliary agent include, but are not limited to, melamine compounds and silane compounds. Examples of the commercially available products of the melamine compounds include, but are not limited to, Cymel-300, Cymel-303, and the like manufactured by Mitsui Chemicals; and MW-30 MH, MW-30, MS-11, MS-001, MX-750, MX-706, and the like manufactured by Sanwa Chemical. Examples of the silane compounds include, but are not limited to, vinyltrimethoxysilane, vinyltriethoxysilane, 3-acryloxypropyltrimethoxy silane, vinyltri(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropyldimethylmethoxysilane, 2-(3,4-epoxycyclohexyl)ethyltrimethoxysilane, 3-chloropropylmethyldimethoxysilane, 3-chloropropyltrimethoxysilane, 3-methylallyloxypropyltrimethoxysilane, 3-mercaptopropyltrimethoxysilane, and commercially available products manufactured by Shin-Etsu Chemical Co., Ltd. (for example, KMB403).

The melamine compounds used as the adhesion auxiliary agent are in an amount ranging preferably from 0 to 20 parts by weight, more preferably from 0.5 part by weight to 18 parts by weight, and most preferably from 1.0 part by weight to 15 parts by weight based on 100 parts by weight of the polysiloxane (A).

The silane compounds used as the adhesion auxiliary agent are in an amount ranging preferably from 0 to 2 parts by weight, more preferably from 0.05 part by weight to 1 part by weight, and most preferably from 0.1 part by weight to 0.8 part by weight based on 100 parts by weight of the polysiloxane (A).

Examples of the surfactant include, but are not limited to, anionic surfactant, cationic surfactant, nonionic surfactant, amphoteric surfactant, polysiloxane surfactant, fluorinated surfactant, and combinations thereof. Examples of the surfactant include, but are not limited to: (1) polyoxyethylene alkyl ethers, for example, polyoxyethylene lauryl ether, and the like; (2) polyoxyethylene alkyl phenyl ethers, for example, polyoxyethylene octyl phenyl ether, polyoxyethylene nonyl phenyl ether, and the like; (3) polyethylene glycol diesters, for example, polyethylene glycol dilaurate, polyethylene glycol distearate, and the like; (4) sorbitan fatty acid esters; (5) fatty acid modified polyesters; (6) tertiary amine modified polyurethanes, and the like. Examples of commercially available products of the surfactant include KP (manufacture by Shin-Etsu Chemical Co., Ltd.), SF-8427 (manufactured by Toray Dow Corning Silicone), Polyflow (manufactured by Kyoeisha Chemical Co., Ltd.), F-Top (manufactured by Tochem Product Co., Ltd.), Megaface (manufactured by DIC), Fluorade (manufactured by Sumitomo 3M), Surflon (manufactured by Asahi Glass), SINOPOL E8008 (manufactured by Sino-Japan Chemical Co., Ltd.), F-475 (manufactured by DIC), and combinations thereof.

The surfactant is used in an amount ranging from 0.5 part by weight to 50 parts by weight, preferably from 1 part by weight to 40 parts by weight, more preferably from 3 parts by weight to 30 parts by weight based on 100 parts by weight of the polysiloxane (A).

Examples of the defoamer include, but are not limited to, Surfynol MD-20, Surfynol MD-30, EnviroGem AD01, EnviroGem AEO1, EnviroGem AE02, Surfynol DF 110D, Surfynol 104E, Surfynol 420, Surfynol DF 37, Surfynol DF 58, Surfynol DF 66, Surfynol DF 70, and Surfynol DF 210 (manufactured by Air products).

The defoamer is used in an amount ranging preferably from 1 part to 10 parts by weight, more preferably from 2 parts to 9 parts by weight, and most preferably from 3 parts to 8 parts by weight based on 100 parts by weight of the polysiloxane (A).

Examples of the solubility promoter include, but are not limited to, N-hydroxydicarboxylic imide compounds, and phenolic hydroxyl compounds, for example, the hydroxyl compounds used for manufacturing the quinonediazidesulfonic acid ester (B).

The solubility promoter is used in an amount ranging preferably from 1 part by weight to 20 parts by weight, more preferably from 2 parts by weight to 15 parts by weight, and most preferably from 3 parts by weight to 10 parts by weight based on 100 parts by weight of the polysiloxane (A).

The photo-curing polysiloxane composition of the present invention is manufactured by stirring the polysiloxane (A), the quinonediazidesulfonic acid ester (B), the fluorene-containing compound (C) of Formula (II), and the solvent (D) optionally together with the thermal acid generator (E) and the additives (F) in a stirrer to form a homogeneous solution.

A protective film of the present invention is formed by coating the photo-curing polysiloxane composition onto a substrate followed by pre-bake, exposure, development, and post-bake treatments.

The photo-curing polysiloxane composition is applied on the substrate by spin coating, slit coating, roller coating, or the like, and is then prebaked to remove the solvent and to form a prebaked coating film. The conditions for the prebaking depend on the types and the formulating ratio of the components for the photo-curing polysiloxane composition. However, the prebaking is usually conducted at a temperature ranging from 70° C. to 110° C. for a period ranging from 1 minute to 15 minutes. The prebaked coating film is exposed via a photomask using ultraviolet light, such as g-line, h-line, i-line, or the like. The device for providing the ultraviolet light includes a (ultra-) high pressure mercury lamp, or a metal halide lamp. The prebaked coating film after exposing is immersed in a developer solution at a temperature of 23±2° C. for a period ranging from 15 seconds to 5 minutes so as to form a desired pattern. Examples of the developer include alkali compounds, such as sodium hydroxide, potassium hydroxide, sodium carbonate, sodium hydrogen carbonate, potassium carbonate, potassium hydrogen carbonate, sodium silicate, sodium methylsilicate, aqueous ammonia, ethylamine, diethylamine, dimethyl ethanolamine, tetramethylammonium hydroxide, tetraethylammonium hydroxide, choline, pyrrole, piperidine, 1,8-diazabicyclo-[5,4,0]-7-undecene, and the like.

The developer solution is used to reveal defined patterns after exposing the photo-curing polysiloxane composition. When the concentration of the developer solution is too high, the specific patterns will be damaged or have deteriorated resolution. When the concentration of the developer solution is too low, the specific patterns will not be formed or residue after development may be formed due to poor development. The concentration of the developer solution will influence the patterns formed by the photo-curing polysiloxane composition after exposure. Preferably, the developer solution is used in a concentration ranging preferably from 0.001 wt % to 10 wt %, more preferably from 0.005 wt % to 5 wt %, and most preferably from 0.01 wt % to 1 wt %.

In the illustrative examples of this invention, 2.38 wt % of tetramethylammonium hydroxide was used as the developer solution. The developer solution of 2.38 wt % is commonly used in the art while the developer solution less than 2.38 wt % can be used, if required. The developer solution of 2.38 wt % can be used for developing the photo-curing polysiloxane composition in this invention. The photo-curing polysiloxane composition is capable of forming fine patterns even when a developer solution less than 2.38 wt % is used.

The developer solution is removed by washing with water after developing. The coating film formed on the substrate is dried with compressed air or nitrogen, and is then post-baked using a heating device, such as a hot plate or an oven. The post-baking is conducted at a temperature ranging from 100° C. to 250° C. for a period ranging from 1 minute to 60 minutes if the hot plate is used or for a period ranging from 5 minutes to 90 minutes if the oven is used. A protective film is formed on the substrate after the aforementioned process.

Examples of the substrate suitable for the present invention include alkali-free glass, soda-lime glass, Pyrex glass, quartz glass, a glass coated with a transparent conductive film thereon, and the like commonly used in a liquid crystal display; and a photoelectric conversion substrate (for example, a silicon substrate) used in a solid-state image sensor.

An element including the substrate and the protective film formed from the photo-curing polysiloxane composition of the present invention applied on the substrate can be used in a display device, a semiconductor device, an optical waveguide device, and the like.

The following examples are provided to illustrate the preferred embodiments of the invention, and should not be construed as limiting the scope of the invention.

### EXAMPLES

### Preparation of Polysiloxane (A)

### Preparation Example A-1

A 500 ml three-necked flask was added with methyltrimethoxysilane (referred to as MTMS, 0.3 mole), phenyltrimethoxysilane (referred to as PTMS, 0.65 mole), GF-20 (0.05 mole), and propylene glycol monoethyl ether (referred to as PGEE, 200 g). Stirring was conducted at room temperature while an oxalic acid aqueous solution (0.40 g oxalic acid/75 g H₂O) was added over 30 minutes. The mixture in the flask was then stirred in an oil bath at a temperature of 30° C. for 30 minutes. The temperature of the oil bath was raised to 120° C. within a succeeding 30 minutes. When the temperature of the mixture in the flask reached 105° C., the mixture in the flask was stirred for a further 6 hours to carry out polycondensation reaction. The polysiloxane (A-1) was obtained after distillation to remove the solvent.

### Preparation Example A-2

A 500 ml three-necked flask was added with dimethyldimethoxysilane (referred to as DMDMS, 0.40 mole), PTMS (0.40 mole), phenyltriethoxysilane (referred to as PTES, 0.10 mole), GF-20 (0.05 mole), 3-(trimethoxysilyl)propyl glutaric anhydride (referred to as TMSG, 0.05 mole) PGEE (100 g), and diacetone alcohol (referred to as DAA, 100 g). Stirring was conducted at room temperature while an oxalic acid aqueous solution (0.40 g oxalic acid/75 g H₂O) was added over 30 minutes. The mixture in the flask was then stirred in an oil bath at a temperature of 30° C. for 30 minutes. The temperature of the oil bath was raised to 120° C. within a succeeding 30 minutes. When the temperature of the mixture in the flask reached 110° C., the mixture in the flask was stirred for a further 5 hours to carry out polycondensation reaction. The polysiloxane (A-2) was obtained after distillation to remove the solvent.

### Preparation Example A-3

A 500 ml three-necked flask was added with DMDMS (0.60 mole), PTMS (0.30 mole), 3-glycidoxypropyltrimethoxysilane (referred to as TMS-GAA, 0.10 mole) and PGEE (200 g). Stirring was conducted at room temperature while an oxalic acid aqueous solution (0.35 g oxalic acid/75 g H₂O) was added over 30 minutes. The mixture in the flask was then stirred in an oil bath at a temperature of 30° C. for 30 minutes. The temperature of the oil bath was raised to 120° C. within a succeeding 30 minutes. When the temperature of the mixture in the flask reached 105° C., the mixture in the flask was stirred for a further 6 hours to carry out polycondensation reaction to form the polysiloxane (A-3).

### Preparation Example A-4

A 500 ml three-necked flask was added with MTMS (0.65 mole), PTES (0.25 mole), 2-oxetanylbutoxypropyltrimethoxysilane (referred to as TMSOX-D, 0.09 mole), DMS-S27 (0.01 mole), and PGEE (200 g). Stirring was conducted at room temperature while an oxalic acid aqueous solution (0.45 g oxalic acid/75 g H₂O) was added over 30 minutes. The mixture in the flask was then stirred in an oil bath at a temperature of 30° C. for 30 minutes. The temperature of the oil bath was raised to 120° C. within a succeeding 30 minutes. When the temperature of the mixture in the flask reached 110° C., the mixture in the flask was stirred for a further 6 hours to carry out polycondensation reaction. The polysiloxane (A-4) was obtained after distillation to remove the solvent.

### Preparation Example A-5

A 500 ml three-necked flask was added with MTMS (0.75 mole), PTMS (0.25 mole), and PGEE (200 g). Stirring was conducted at room temperature while an oxalic acid aqueous solution (0.45 g oxalic acid/75 g H₂O) was added over 30 minutes. The mixture in the flask was then stirred in an oil bath at a temperature of 30° C. for 30 minutes. The temperature of the oil bath was raised to 120° C. within a succeeding 30 minutes. When the temperature of the mixture in the flask reached 105° C., the mixture in the flask was stirred for a further 6 hours to carry out polycondensation reaction. The polysiloxane (A-5) was obtained after distillation to remove the solvent.

### Preparation Example A-6

A 500 ml three-necked flask was added with MTMS (0.40 mole), DMDMS (0.30 mole), PTMS (0.20 mole), PTES (0.10 mole), and PGEE (200 g). Stirring was conducted at room temperature while an oxalic acid aqueous solution (0.45 g oxalic acid/75 g H₂O) was added over 30 minutes. The mixture in the flask was then stirred in an oil bath at a temperature of 30° C. for 30 minutes. The temperature of the oil bath was raised to 120° C. within a succeeding 30 minutes. When the temperature of the mixture in the flask reached 110° C., the mixture in the flask was stirred for a further 6 hours to carry out polycondensation reaction. The polysiloxane (A-6) was obtained after distillation to remove the solvent.

The types and the amounts of the silane monomer components, the solvent, and the catalysts, and the reaction conditions used in Preparation Examples A-1 to A-6 are listed in Table 1.

TABLE 1

| | | | | | | | | | | | | | | | Poly- |
|---|---|---|---|---|---|---|---|---|---|---|---|---|---|---|---|
| | Compositions | | | | | | | | | | | | | | conden- |
| | Silane monomers/Siloxane Prepolymers(moles) | | | | | | | | | | | Catalysts(g) | | Reaction | sation |
| Prep. | | | | | TMS- | GF- | | | DMS- | Solvents(g) | | | Oxalic | Temp. | Time |
| Ex. | MTMS | DMDMS | PTMS | PTES | GAA | 20 | TMSG | TMSOX-D | S27 | PGEE | DAA | Water | Acid | (° C.) | (hrs) |
| A-1 | 0.30 | — | 0.65 | — | — | 0.05 | — | — | — | 200 | — | 75 | 0.40 | 105 | 6 |
| A-2 | — | 0.40 | 0.40 | 0.10 | — | 0.05 | 0.05 | — | — | 100 | 100 | 75 | 0.40 | 110 | 5 |
| A-3 | — | 0.60 | 0.30 | — | 0.10 | — | — | — | — | 200 | — | 75 | 0.35 | 105 | 6 |
| A-4 | 0.65 | — | — | 0.25 | — | — | — | 0.09 | 0.01 | 200 | — | 75 | 0.45 | 110 | 6 |
| A-5 | 0.75 | — | 0.25 | — | — | — | — | — | — | 200 | — | 75 | 0.45 | 105 | 6 |
| A-6 | 0.40 | 0.30 | 0.20 | 0.10 | — | — | — | — | — | 200 | — | 75 | 0.45 | 110 | 6 |

MTMS: methyltrimethoxysilane;
DMDMS: dimethyldimethoxysilane;
PTMS: phenyltrimethoxysilane:
PTES: phenyltriethoxysilane;
TMS-GAA: 3-glycidoxypropyltrimethoxysilane;
GF-20: 3-(triethoxysilyl) propyl succinic anhydride;
TMSG: 3-(trimethoxysilyl) propyl glutaric anhydride;
TMSOX-D: 2-oxetanylbutoxypropyltrimethoxysilane;
DMS-S27: silanol terminal polysiloxanes manufactured by Gelest Inc.;
PGEE: propylene glycol monoethyl ether;
DAA: diacetone alcohol.

### Preparation of Photo-Curing Polysiloxane Composition:

### Example 1

100 parts by weight of the polysiloxane (A-1) obtained in Preparation Example A-1, 2 parts by weight of an o-naphthoquinonediazidesulfonic acid ester compound (DPAP200 manufactured by DKC, average esterification rate: 67%) obtained by reacting 1-[1-(4-hydroxyphenyl)isopropyl]-4-[1,1-bis(4-hydroxyphenyl)ethyl]benzene with o-naphthoquinonediazo-5-sulfonic acid, and 5 parts by weight of 9,9-bis(4-aminophenyl)fluorene were added into 50 parts by weight of PGMEA. Stirring was conducted using a shaking type stirrer until a homogenous photo-curing polysiloxane composition was obtained. The obtained photo-curing polysiloxane composition was evaluated according to the following evaluation methods. The evaluation results are shown in Table 2.

### Examples 2 to 12 and Comparative Examples 1 to 9

Examples 2 to 12 and Comparative Examples 1 to 9 were conducted in a manner identical to that of Example 1 using the components and the amounts thereof shown in Tables 2 and 3. The obtained photo-curing polysiloxane compositions of Examples 2 to 12 and Comparative Examples 1 to 9 were evaluated according to the following evaluation methods. The evaluation results are shown in Tables 2 and 3.

### Evaluation Methods:

### 1. Sensitivity:

The photo-curing polysiloxane compositions obtained in Examples 1 to 12 and Comparative Examples 1 to 9 were separately spin-coated on glass substrates of 100 mm×100 mm×0.7 mm to obtain pre-coated films of 2 μm in thickness followed by pre-baking at 110° C. for 2 minutes. The pre-coated films were then treated with ultra-violet irradiation using an exposure machine (Model No. AG250-4N-D-A-S-H, manufactured by M & R Nano Technology Co., Ltd.) through suitable photo-masks in a 30 μm spacing, and were then immersed in a developer solution of 2.38 wt % tetramethylammonium hydroxide solution at 23° C. for 1 minute to dissolve the exposed portions of the pre-coated films followed by washing with pure water. The evaluation was conducted by determining the exposure energy (mJ) required for each exposure area (0.5 cm×0.5 cm) to be fully developed. Lower exposure energy required for each exposure area to be fully developed means better sensitivity.

∘: exposure energy≦60 mJ;

Δ: 60 mJ<exposure energy≦100 mJ;

X: 100 mJ<exposure energy.

### 2. Chemical Resistance:

The photo-curing polysiloxane compositions obtained in Examples 1 to 12 and Comparative Examples 1 to 9 were separately spin-coated on glass substrates of 100 mm×100 mm×0.7 mm to obtain pre-coated films of 2 μm in thickness followed by pre-baking at 110° C. for 2 minutes. The pre-coated films were treated with ultra-violet irradiation with energy intensity of 100 mJ/cm² using an exposure machine through suitable photo-masks, and were then immersed in a developer solution of 2.38 wt % tetramethylammonium hydroxide solution for 60 seconds to dissolve the exposed portions of the pre-coated films followed by washing with pure water. The developed films were directly irradiated by the exposure machine with energy intensity of 200 mJ/cm². Then, post-bake at 230° C. was conducted at distinct periods. The post-baked films were then immersed in TOK106 solution at 60° C. for 6 minutes. Variations of film thickness were calculated through the following formula:

Variation of film thickness=[(film thickness after immersion−film thickness before immersion)/film thickness before immersion]×100%

The variation of film thinness ranging from −3% to 3% is preferable.

⊚: −3%≦variation of film thinness≦3%;

∘: −5%≦variation of film thinness≦5%;

X: variation of film thinness>5% or variation of film thinness<−5%.

### 3. Hardness:

The photo-curing polysiloxane compositions obtained in Examples 1 to 12 and Comparative Examples 1 to 9 were separately spin-coated on glass substrates of 100 mm×100 mm×0.7 mm to obtain pre-coated films of 2 μm in thickness followed by pre-baking at 110° C. for 2 minutes. The pre-coated films were treated with ultra-violet irradiation with energy intensity of 100 mJ/cm² using an exposure machine through suitable photo-masks, and were then immersed in a developer solution of 2.38 wt % tetramethylammonium hydroxide solution for 60 seconds to dissolve the exposed portions of the pre-coated films followed by washing with pure water. The developed films were directly irradiated by the exposure machine with energy intensity of 200 mJ/cm². Then, post-bake at 230° C. was conducted at distinct periods to obtain protective films on the glass substrates. The protective films were tested by a pencil hardness tester (Model P-247, manufactured by Mitsubishi). Measurement conditions of 500 g weight and 0.5 mm/sec moving rate were applied.

Hardness is defined as follows:

⊚: hardness≧5H;

∘: hardness=4H;

Δ: hardness=3H;

X: hardness≦2H.

TABLE 2

| Components | | Examples | | | | | | | | | | | |
|---|---|---|---|---|---|---|---|---|---|---|---|---|---|
| (parts by weight) | | 1 | 2 | 3 | 4 | 5 | 6 | 7 | 8 | 9 | 10 | 11 | 12 |
| (A) | A-1 | 100 | 100 | — | 50 | 30 | — | 50 | — | — | — | — | — |
| | A-2 | — | — | 100 | 50 | 70 | 100 | 50 | — | — | — | — | — |
| | A-3 | — | — | — | — | — | — | — | 100 | 30 | — | 70 | 100 |
| | A-4 | — | — | — | — | — | — | — | — | 70 | 100 | 30 | — |
| | A-5 | — | — | — | — | — | — | — | — | — | — | — | — |
| | A-6 | — | — | — | — | — | — | — | — | — | — | — | — |
| (B) | B-1 | 2 | 5 | 40 | 50 | 10 | 30 | 40 | 20 | 40 | — | — | 20 |
| | B-2 | — | — | — | — | — | — | — | — | — | 20 | 40 | 20 |
| (C) | C-1 | — | — | — | — | 10 | 60 | — | 60 | — | 30 | — | 50 |
| | C-2 | — | — | — | — | — | — | 80 | — | 120 | — | 70 | 50 |
| | C-3 | 5 | — | 100 | — | 10 | — | — | — | — | — | — | — |
| | C-4 | — | 20 | — | 120 | — | — | — | — | — | — | — | — |
| (D) | D-1 | 50 | 100 | 1000 | — | 200 | — | 500 | — | — | — | 200 | — |
| | D-2 | — | — | — | 1200 | — | 400 | — | 500 | 800 | 500 | 1000 | 1000 |
| | D-3 | — | — | — | — | — | — | 100 | — | — | — | — | — |
| (E) | E-1 | — | 1 | — | — | — | — | — | — | — | — | — | — |
| | E-2 | — | — | — | — | — | — | — | — | — | 2 | — | — |
| Evaluation | Sensitivity | ◯ | ◯ | ◯ | ◯ | ◯ | ◯ | ◯ | ◯ | ◯ | ◯ | ◯ | ◯ |
| Items | Chemical | ⊚ | ⊚ | ⊚ | ⊚ | ⊚ | ◯ | ◯ | ⊚ | ⊚ | ⊚ | ⊚ | ⊚ |
| | Resistance | | | | | | | | | | | | |
| | Hardness | ◯ | ⊚ | ◯ | ◯ | ◯ | ◯ | ◯ | ◯ | ◯ | ⊚ | ◯ | ◯ |

B-1: o-naphthoquinonediazidesulfonic acid ester compound obtained by reacting 1-[1-(4-hydroxyphenyl)isopropyl]-4-[1,1-bis(4-hydroxyphenyl)ethyl]benzene with o-naphthoquinonediazo-5-sulfonic acid;
B-2: an o-naphthoquinonediazidesulfonic acid ester compound obtained by reacting 2,3,4-trihydroxybenzophenone with o-naphthoquinonediazo-5-sulfonic acid;
C-1: 9,9-bis(4-aminophenyl)fluorene manufactured by JFE Chemical;
C-2: 9,9-bis (3,4-dicarboxyphenyl)fluorene dianhydride manufactured by JFE Chemical;
C-3: 9,9-bis[(4-glycidoxy)phenyl]fluorene manufactured by Osaka Gas, model name: OGSOL PG-100;
C-4: 9,9-bis[4-(2-glycidoxyethoxy)phenyl]fluorene manufactured by Osaka Gas, model name: OGSOL EG-100;
D-1: propylene glycol monomethylether acetate;
D-2: diacetone alcohol;
D-3: cyclohexanone;
E-1: SI-150;
E-2: 4-hydroxyphenyldimethylsulfonium.

TABLE 3

| Components | | Comparative Examples | | | | | | | | |
|---|---|---|---|---|---|---|---|---|---|---|
| (parts by weight) | | 1 | 2 | 3 | 4 | 5 | 6 | 7 | 8 | 9 |
| (A) | A-1 | — | — | — | — | — | 100 | — | — | — |
| | A-2 | — | — | — | — | — | — | 100 | — | — |
| | A-3 | — | — | — | 100 | — | — | — | 100 | — |
| | A-4 | — | — | — | — | 100 | — | — | — | 100 |
| | A-5 | 100 | — | 100 | — | — | — | — | — | — |
| | A-6 | — | 100 | — | — | — | — | — | — | — |
| (B) | B-1 | 30 | — | 30 | — | 30 | 20 | 20 | 40 | 40 |
| | B-2 | — | 30 | — | 30 | — | — | — | — | — |
| (C) | C-1 | 30 | — | — | — | — | — | — | — | — |
| | C-2 | — | — | — | — | — | — | — | — | — |
| | C-3 | — | 60 | — | — | 90 | — | — | — | — |
| | C-4 | — | — | — | 60 | — | — | — | — | — |
| (D) | D-1 | 500 | 500 | 500 | 500 | 800 | 1000 | 1000 | 1000 | — |
| | D-2 | — | — | — | 300 | — | — | — | — | 1000 |
| | D-3 | — | — | — | — | — | — | — | — | — |
| (E) | E-1 | — | — | — | — | — | — | — | — | — |
| | E-2 | — | — | — | — | — | — | — | — | — |
| Evaluation | Sensitivity | X | X | X | ◯ | ◯ | ◯ | ◯ | ◯ | ◯ |
| Items | Chemical Resistance | X | X | X | X | X | X | X | X | X |
| | Hardness | Δ | Δ | Δ | Δ | Δ | Δ | Δ | Δ | Δ |

B-1: o-naphthoquinonediazidesulfonic acid ester compound obtained by reacting 1-[1-(4-hydroxyphenyl)isopropyl]-4-[1,1-bis(4-hydroxyphenyl)ethyl]benzene with o-naphthoquinonediazo-5-sulfonic acid;
B-2: an o-naphthoquinonediazidesulfonic acid ester compound obtained by reacting 2,3,4-trihydroxybenzophenone with o-naphthoquinonediazo-5-sulfonic acid;
C-1: 9,9-bis(4-aminophenyl)fluorene manufactured by JFE Chemical;
C-2: 9,9-bis(3,4-dicarboxyphenyl)fluorene dianhydride manufactured by JFE Chemical;
C-3: 9,9-bis[(4-glycidoxy)phenyl]fluorene manufactured by Osaka Gas, model name: OGSOL PG-100;
C-4: 9,9-bis[4-(2-glycidoxyethoxy)phenyl]fluorene manufactured by Osaka Gas, model name: OGSOL EG-100;
D-1: propylene glycol monomethylether acetate;
D-2: diacetone alcohol;
D-3: cyclohexanone;
E-1: SI-150;
E-2: 4-hydroxyphenyldimethylsulfonium.

As shown in Table 2, the photo-curing polysiloxane composition formed with anhydride group-containing or/and epoxy group-containing polysiloxane (A) has high sensitivity in the photolithography process. Meanwhile, chemical resistance of the protective film formed using the photo-curing polysiloxane composition is increased through a reaction of the reactive group of the polysiloxane (A) with the reactive group of the fluorene-containing compound (C) represented by Formula (II).

Specifically, chemical resistance of the protective film formed using the photo-curing polysiloxane composition is increased as shown in Examples 1 to 5 attributed to the anhydride group-containing polysiloxane (A) together with the fluorene-containing compound (C) having epoxy group. As shown in Examples 8 to 12, the epoxy group-containing polysiloxane (A) used together with the fluorene-containing compound (C) having amino group or/and anhydride group can reach the same effect of increased chemical resistance of the protective film.

As shown in Comparative Examples 3, 6, 7, 8 and 9, the fluorene-containing compound (C) represented by Formula (II) is not used in the photo-curing polysiloxane compositions. Therefore, the protective films formed from the photo-curing polysiloxane compositions have deteriorated chemical resistance and hardness.

As shown in Comparative Examples 1 and 2, the anhydride group-containing or/and epoxy group-containing polysiloxane (A) is not used in the photo-curing polysiloxane compositions. Therefore, the sensitivity of the photo-curing polysiloxane compositions is not good and the protective films formed from the photo-curing polysiloxane compositions have deteriorated chemical resistance and hardness.

As shown in Comparative Examples 4 and 5, the epoxy group-containing polysiloxane (A) was used together with the fluorene-containing compound (C) having epoxy group in the photo-curing polysiloxane compositions. The protective films thus formed from the photo-curing polysiloxane compositions have deteriorated chemical resistance and hardness.

In view of the aforesaid, the protective film in this invention formed from the photo-curing polysiloxane composition has better chemical resistance through use of the specific polysiloxane (A) and the specific fluorene-containing compound (C) represented by Formula (II) to form a dense structure. In the meantime, the photo-curing polysiloxane composition has high sensitivity in lithography process attributed to the anhydride group-containing or/and epoxy group-containing polysiloxane (A).

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A photo-curing polysiloxane composition, comprising:
a polysiloxane obtained by subjecting a silane monomer component to condensation, said silane monomer component including a silane monomer of formula (I):
Si(R^{a})ₜ(OR^{b})₄₋ₜ (I)
wherein
t denotes an integer ranging from 1 to 3,
when t is 1, R^{a} is selected from the group consisting of an anhydride-substituted C₁-C₁₀ alkyl group, an epoxy-substituted C₁-C₁₀ alkyl group, and an epoxy-substituted alkoxy group,
when t is 2 or 3, at least one of R^{a}s is selected from the group consisting of an anhydride-substituted C₁-C₁₀ alkyl group, an epoxy-substituted C₁-C₁₀ alkyl group, and an epoxy-substituted alkoxy group, and the rest of R^{a}s is selected from the group consisting of hydrogen, a C₁-C₁₀ alkyl group, a C₂-C₁₀ alkenyl group, and a C₆-C₁₅ aryl group, R^{a}s being identical or different, and
R^{b} is selected from the group consisting of a hydrogen atom, a C₁-C₆ alkyl group, a C₁-C₆ acyl group, and a C₆-C₁₅ aryl group, R^{b}s being identical or different when 4-t is 2 or 3;
a quinonediazidesulfonic acid ester;
a fluorene-containing compound of formula (II): 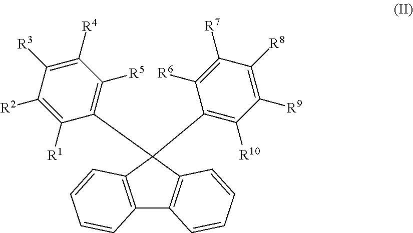
wherein
at least one of R¹-R¹⁰ includes a reactive group which is selected from the group consisting of an epoxy-containing group, a carboxy-containing group, an anhydride-containing group, and an amino-containing group; and
a solvent,
with the proviso that when said at least one of R^{a} is said epoxy-substituted C₁-C₁₀ alkyl group or said epoxy-substituted alkoxy group, said reactive group is not said epoxy-containing group.

2. The photo-curing polysiloxane composition as claimed in claim 1, wherein said at least one of R^{a} is said anhydride-substituted C₁-C₁₀ alkyl group and said reactive group is said epoxy-containing group.

3. The photo-curing polysiloxane composition as claimed in claim 1, wherein said at least one of R^{a} is selected from the group consisting of said epoxy-substituted C₁-C₁₀ alkyl group and said epoxy-substituted alkoxy group, and said reactive group is selected from the group consisting of said carboxy-containing group and said amino-containing group.

4. The photo-curing polysiloxane composition as claimed in claim 1, wherein said fluorene-containing compound is in an amount ranging from 5 to 120 parts by weight based on 100 parts by weight of said polysiloxane.

5. The photo-curing polysiloxane composition as claimed in claim 1, wherein said quinonediazidesulfonic acid ester is in an amount ranging from 1 to 50 parts by weight based on 100 parts by weight of said polysiloxane.

6. The photo-curing polysiloxane composition as claimed in claim 1, wherein said solvent is in an amount ranging from 50 to 1,200 parts by weight based on 100 parts by weight of said polysiloxane.

7. The photo-curing polysiloxane composition as claimed in claim 1, further comprising a thermal acid generator.

8. The photo-curing polysiloxane composition as claimed in claim 7, wherein said thermal acid generator is in an amount ranging from 0.5 to 20 parts by weight based on 100 parts by weight of said polysiloxane.

9. A protective film adapted to be formed on a substrate, said protective film being formed by coating the photo-curing polysiloxane composition as claimed in claim 1 onto a substrate followed by pre-bake, exposure, development, and post-bake treatments.

10. An element, comprising a substrate, and the protective film as claimed in claim 9 applied on said substrate.
